(19) United States
(12) Patent Application Publication
(10) Pub. No.: US 2021/0333317 A1
(43) Pub. Date: Oct. 28, 2021

(54) Button Module

(71) Applicant: Traitel Technologies Corporation, Wilimington, DE (US)

(72) Inventor: Eli M. Traitel, San Diego, CA (US)

(73) Assignee: Traitel Technologies Corporation, Wilmington, DE (US)

(21) Appl. No.: 17/169,460

(22) Filed: Feb. 6, 2021

Related U.S. Application Data
(63) Continuation of application No. PCT/US19/45348, filed on Aug. 6, 2019.

(30) Foreign Application Priority Data
Aug. 7, 2018 (AU) 2018902866

(51) Int. Cl. G01R 31/28; H04W 24/00

(52) U.S. Cl. CPC G01R 31/2837; G01R 31/2863; H04W 24/00

(57) ABSTRACT

A button module that includes a housing having a user operable button, a circuit board within the housing and a removable electrical connector, wherein a second module can be electrically connected at the electrical connection, wherein the button module can perform one or more functions in signal-communication with the second module through the electrical connection, such as perform one or more functions programmed on the circuit board utilizing electrical circuits in the second module, or the circuit board being configured to communicate with one or more wireless devices over one or more wireless networks.

This application is a continuation of International Application PCT/US19/45348, filed Aug. 6, 2019.

### TECHNICAL FIELD

The present invention relates to a button module and more specifically, a button module in a physical device, capable of performing multiple functions.

### BACKGROUND

The following background includes information that may be useful in understanding the present invention. It is not an admission that any of the information provided herein is prior art or relevant to the presently claimed invention, or that any publication specifically or implicitly referenced is prior art.

Buttons configured for communicating over wireless networks are known. These known buttons have limited functionality, may not be reprogrammable, and/or may not be easily modified to increase the functionality of the button.

In light of the above, several wireless devices may need to be provided to meet the needs of a user. Each wireless device that is able to communicate over one or more wireless networks typically needs to be tested to determine if the device complies with the requirements of one or more of the wireless networks. Such testing can be expensive. Accordingly, for several wireless devices, testing each device can be a very expensive task.

### SUMMARY

The exemplary embodiments of the present invention provide a button module that includes a housing having a user operable button, a circuit board within the housing and a removable electrical connector, wherein a second module can be electrically connected at the electrical connection, wherein the button module can perform one or more functions in signal-communication with the second module through the electrical connection, such as perform one or more functions programmed on the circuit board utilizing electrical circuits in the second module, or the circuit board being configured to communicate with one or more wireless devices over one or more wireless networks.

According to one aspect of the present invention, there is provided a button module comprising:

a housing having a socket and a button;

so a circuit board disposed within the housing,

wherein the button module comprises:

a first operating configuration in which the circuit board is configured to perform one or more functions programmed on the circuit board independent of the button and/or perform one or more functions programmed on the circuit board in response to actuation of the button; and

a second operating configuration in which an electronic circuit of one of a plurality of electronic modules is removably received in the socket such that the electronic circuit is electrically connected to the circuit board, the circuit board being configured to utilize the electronic circuit to perform one or more functions programmed on the circuit board independent of the button being actuated and/or to utilize the electronic circuit to perform one or more functions programmed on the circuit board in response to actuation of the button.

The button module can comprise a power supply within the housing, the power supply being electrically connected to the circuit board to supply power to the circuit board. Additionally, the electronic circuit of the one of a plurality of electronic modules can be electrically connected to the power supply when removably received in the socket.

The circuit board may be disposed within the housing in a vertical position.

According to another aspect of the present invention, there is provided a button module comprising:

a housing having a socket and a button;

a circuit board disposed within the housing, the circuit board being configured to communicate with one or more wireless devices over one or more wireless networks;

wherein the button module comprises:

a first operating configuration in which the circuit board is configured to perform one or more functions programmed on the circuit board independent of the button and/or perform one or more functions programmed on the circuit board in response to actuation of the button; and

a second operating configuration in which an electronic circuit of one of a plurality of electronic modules is removably received in the socket such that the electronic circuit is electrically connected to the circuit board, the circuit board being configured to utilize the electronic circuit to perform one or more functions programmed on the circuit board independent of the button being actuated and/or to utilize the electronic circuit to perform one or more functions programmed on the circuit board in response to actuation of the button.

The button module can comprise a power supply within the housing, the power supply being electrically connected to the circuit board to supply power to the circuit board. Additionally, the electronic circuit of the one of a plurality of electronic modules can be electrically connected to the power supply when removably received in the socket.

According to another aspect of the present invention, there is provided a button module comprising:

a housing having a socket and a button;

a circuit board disposed within the housing, the circuit board being configured to communicate with one or more wireless devices over one or more wireless networks; and

a power supply disposed within the housing, the power supply being electrically connected to the circuit board to supply power to the circuit board,

wherein the button module comprises:
a first operating configuration in which the circuit board is configured to perform one or more functions programmed on the circuit board independent of the button and/or perform one or more functions programmed on the circuit board in response to actuation of the button; and
a second operating configuration in which an electronic circuit of one of a plurality of electronic modules is removably received in the socket such that the electronic circuit is electrically connected to the circuit board and the power supply, the circuit board being configured to utilize the electronic circuit to perform one or more functions programmed on the circuit board in response to actuation of the button.

In the second operating configuration, the electronic circuit may be powered by the power supply.

In the second operating configuration, the circuit board may control an operation of the electronic circuit.

In the second operating configuration, the respective electronic module may be configured to communicate with the one or more wireless devices over the one or more wireless networks via the circuit board.

The electronic circuit may be formed as a plug to be received in the socket.

The plug may have a shape that complements a shape of the socket.

In the second operating configuration, the housing may be removably coupled to the respective electronic module.

In the second operating configuration, the electronic module coupled to the button module may be configured to removably couple to mains electricity such that the circuit board is configured to receive power from the power supply and/or mains electricity.

In the second operating configuration, the electronic circuit may be configured to be powered by mains electricity, such as domestic AC electric power, and/or the power supply.

The circuit board may have one or more communication modules configured to communicate with the one or more wireless devices over the one or more wireless networks.

The power supply may be a battery.

In the first operating configuration, the button module may further comprise a waterproof cover enclosing the housing to restrict the ingress of water into the housing.

In the second operating configuration, the button module may further comprise a waterproof cover enclosing the housing and the respective electronic module to restrict the ingress of water into the housing and the electronic module.

In the first operating configuration, the circuit board may be configured to perform at least one of the one or more functions in response to the button being actuated according to a predetermined sequence.

In the second operating configuration, the circuit board may be configured to perform at least one of the one or more functions programmed on the circuit board in response to the button being actuated according to a predetermined sequence.

The circuit board may be a printed circuit board.

The electronic circuit may be a printed circuit board.

The circuit board may at least partially define the socket.

According to another aspect of the present invention, there is provided a button module comprising:
a housing having a socket and a button;

a circuit board disposed within the housing, the circuit board being configured to communicate with one or more wireless devices over one or more wireless networks; and

wherein the circuit board is configured to perform one or more functions programmed on the circuit board independent of the button and/or perform one or more functions programmed on the circuit board in response to actuation of the button.

A power supply may be disposed within the housing, the power supply being electrically connected to the circuit board to supply power to the circuit board.

According to another aspect of the present invention, there is provided a button module comprising:
a housing having a socket and a button;

a circuit board disposed within the housing, the circuit board being configured to communicate with one or more wireless devices over one or more wireless networks; and

a power supply disposed within the housing, the power supply being electrically connected to the circuit board to supply power to the circuit board,

so wherein the button module comprises:
a first operating configuration in which the circuit board is configured to perform one or more functions programmed on the circuit board in response to actuation of the button; and
a second operating configuration in which an electronic circuit of one of a plurality of electronic modules is removably received in the socket such that the electronic circuit is electrically connected to the circuit board and the power supply, the circuit board being configured to utilize the electronic circuit to perform one or more functions programmed on the circuit board independent of the button being actuated and/or to utilize the electronic circuit to perform one or more functions programmed on the circuit board in response to actuation of the button.

The summary of the invention does not necessarily disclose all the features essential for defining the invention: the invention may reside in a sub-combination of the disclosed features.

Numerous other advantages and features of the present invention will be become readily apparent from the following detailed description of the invention and the embodiments thereof, and from the accompanying drawings.

### BRIEF DESCRIPTION OF DRAWINGS

A preferred embodiment of the invention will be described hereinafter, by way of example only, with reference to the accompanying drawings, wherein:

FIG. 1 is a top perspective view of a button module according to an aspect of the present invention;

FIG. 2 is a bottom perspective view of the button module of FIG. 1;

FIG. 3 is a top perspective view of the button module of FIG. 1 with the top portion and button omitted;

FIGS. 4a and 4b are front and rear views of the printed circuit board of the button module of FIG. 1;

FIG. 5 is a top perspective view of installing the printed circuit board in the housing of the button module of FIG. 1;

FIG. 6 is a bottom perspective view of installing the printed circuit board in the housing of the button;

FIG. 7 is partial section view of the button module of FIG. 1;

FIG. 8 is a bottom perspective view of the button of the button module of FIG. 1;

FIG. 9 is a perspective view of the button module of FIG. 1 coupled to an electronic module, which is coupled to main electricity;

FIG. 10 is a bottom perspective view of the button module and a top perspective view of the electronic module of FIG. 9 separated from each other;

FIG. 11 is a perspective view of the button module of FIG. 1 installed in a wall; and

FIG. 12 is a block diagram of the printed circuit board of the button module of FIG. 1 communicating over one or more wireless networks.

### DESCRIPTION OF EMBODIMENTS

While this invention is susceptible of embodiment in many different forms, there are shown in the drawings, and will be described herein in detail, specific embodiments thereof with the understanding that the present disclosure is to be considered as an exemplification of the principles of the invention and is not intended to limit the invention to the specific embodiments illustrated.

This application is a continuation of International Application PCT/US19/45348, filed Aug. 6, 2019, herein incorporated by reference in its entirety.

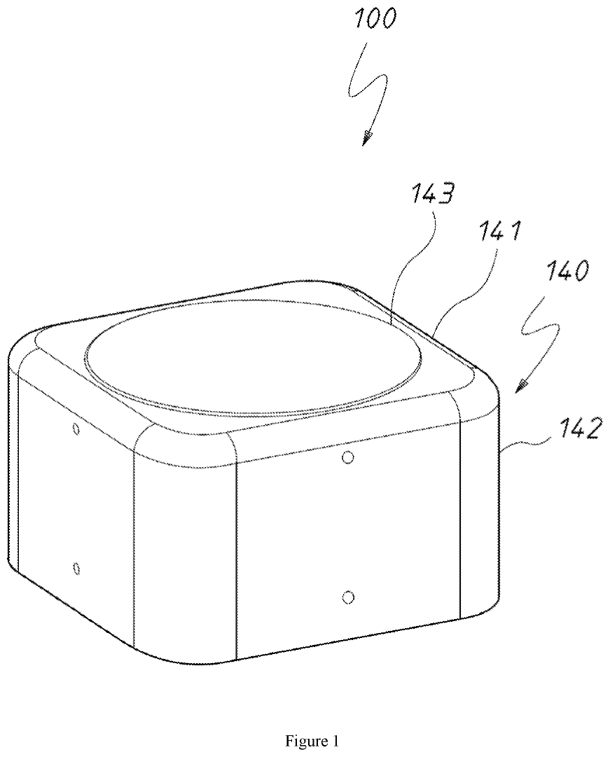

FIGS. 1 to 3 show a button module 100. The button module 100 comprises a printed circuit board (PCB) 110, a power supply 130 shown in the figures as a battery, and a housing 140. Both the PCB 110 and the power supply 130 are disposed within the housing 140. The PCB 110 may be any other type of suitable circuit board known in the art. The power supply 130 may be any other type of suitable power supply known in the art.

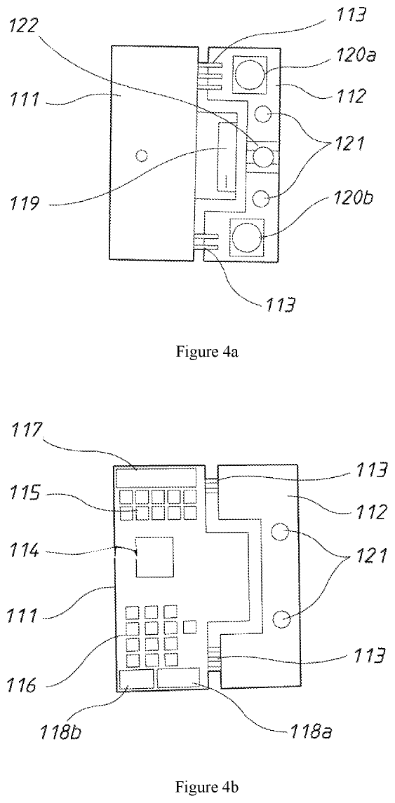

Referring to FIG. 4, the PCB 110 comprises a first part 111 and a second part 112 connected to each other by flexible conductors 113. The flexible conductors 113 also electrically connect the first part 111 and the second part 112 to permit current flow between the first part 111 and the second part 112.

The first part 111 of the PCB 110 comprises a processor module 114, a first set of contact pads 115, a second set of contact pads 116, a first power supply contact 117, second power supply contacts 118a, 118b, and a communications module 119. In its simplest form, the communications module 119 may be an antenna. The second part 112 comprises switches 120a, 120b, a pair of apertures 121, and a light emitting diode 122 (LED).

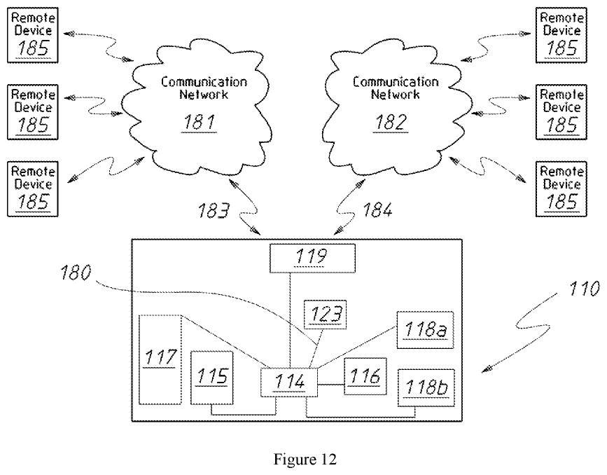

Referring to FIG. 12, the PCB 110 also comprises a storage module 123 that is bi-directionally coupled to the processor module 114 via connection 180. The storage module 123 may be formed from non-volatile semiconductor read only memory (ROM) and semiconductor random access memory (RAM). The RAM may be volatile, non-volatile or a combination of volatile and non-volatile memory. One or more software application programs may be stored in the storage module 123 for use in operating the button module 100. The software application programs may be updated and/or reprogrammed when required through, for example, an application installed on a mobile phone or other electronic device. The software application programs can be loaded into the storage module 123 and be executed by the processor module 114. The software application programs may be pre-installed and stored in the storage module 123 by a manufacturer, prior to distribution of the button module 100. An end user would subsequently update/reprogram the software application programs to meet the needs of the user. In another alternative, the software application programs may be read by the processor module 114 from a communication network 181, or loaded into the storage module 123 from other computer readable media. Computer readable storage media refers to any non-transitory tangible storage medium that participates in providing instructions and/or data to the program module 114 for execution and/or processing. Examples of such storage media include floppy disks, magnetic tape, CD-ROM, a hard disk drive, a ROM or integrated circuit, USB memory, a magneto-optical disk, flash memory, or a computer readable card such as a PCMCIA card and the like, whether or not such devices are internal or external of the module 100.

The software application programs executable by the processor module 114 may be stored in the storage module 123 and be updated and/or reprogrammed to perform one or more functions. The software application programs may be programmed to perform the one or more functions through, for example, a further application program installed on a mobile phone or other electronic device.

The software application programs executable by the processor module 114 may be programmed to perform one or more predetermined functions. The software application programs executable by the processor module 114 may be programmed such that the processor module 114 can perform other functions depending on the needs of a user.

Referring to FIG. 12, the communications module 119 of the PCB 110 is configured to communicate with one or more wireless devices over one or more communications networks 181, 182 via connections 183 and 184, for example. The connections 183 and 184 may be wired or wireless. For example, the connection 183 may be radio frequency or optical. An example of a wired connection includes Ethernet. Further, an example of wireless connection includes Bluetooth™ type local interconnection, Wi-Fi (including protocols based on the standards of the IEEE 802.11 family), Infrared Data Association (IrDa) and the like.

The communications module 119 is configured to transmit signals from the PCB 110 to the one or more remote devices (e.g., 185) and to transmit signals to the PCB 110 from the one or more remote devices 185 over the one or more networks 181, 182.

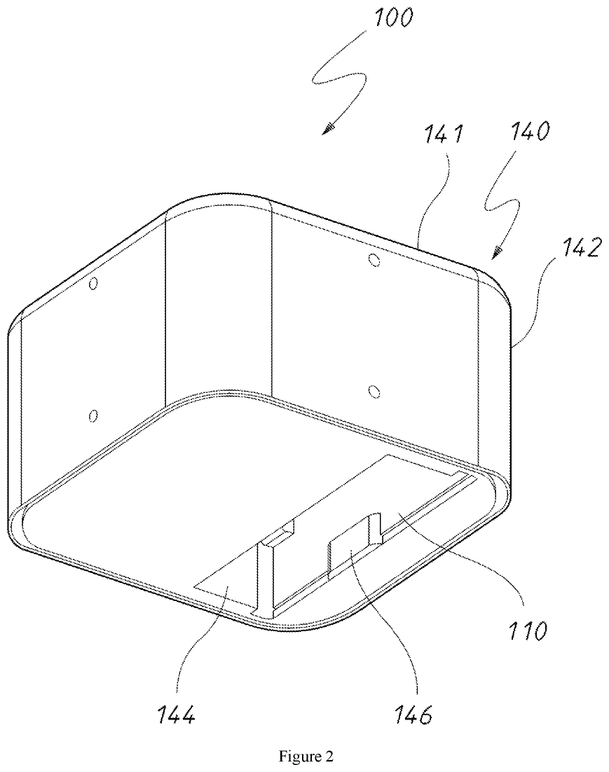

Referring to FIGS. 1 and 2, the housing 140 comprises a top portion 141 coupled to a bottom portion 142, and a button 143 located within, and extending through, the top portion 141.

The bottom portion 142 comprises a socket 144 that extends into the housing 140. The top portion 141, the bottom portion 142, and the button 143 define the housing 140 in which the PCB 110 and the power supply 130 are disposed.

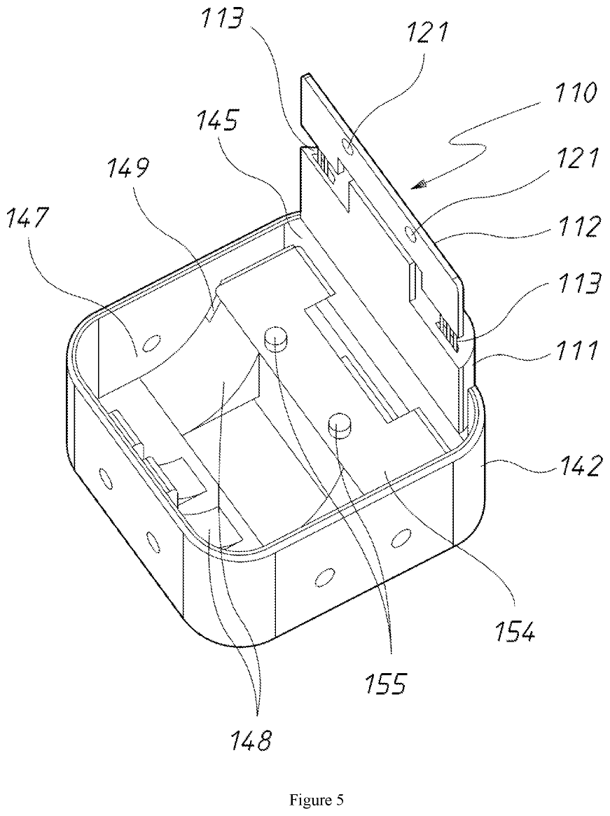

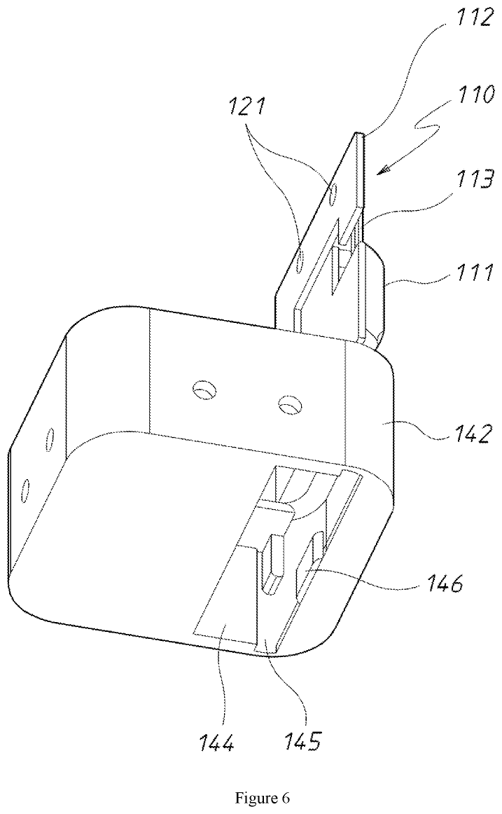

Referring to FIGS. 5 and 6, the bottom portion 142 of the housing 140 has a slot 145 for receiving the first part 111 of the PCB 110 therein. The slot 145 has a stop 146 that holds the PCB 110 within the housing 140 and prevents the PCB 110 from falling through the socket 144.

The bottom portion 142 of the housing 140 has a space 147 having a number of ribs 148. The space 147 and the ribs 148 are configured to receive and correctly locate the power supply 130 within the housing 140.

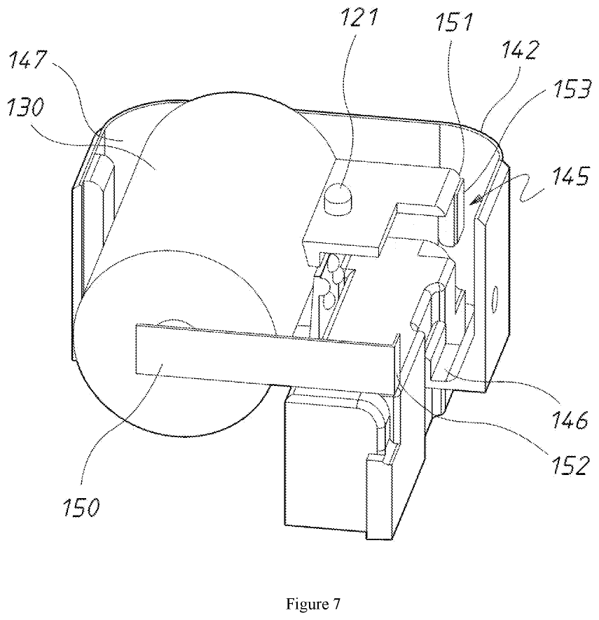

The bottom portion 142 has a pair of channels 149 (only one labelled for clarity of illustration) that each receive a respective contact arm 150, 151 (see FIG. 7).

Referring to FIG. 7, each contact arm 150, 151 comprises a respective hook portion 152, 153. Each contact arm 150, 151, extends through a respective channel 149 such that the hook portion 152, 153 of each contact arm 150, 151 is located within the slot 145, while the other end of each contact arm 150, 151 is located within the space 147. The contact arms 150, 151 electrically connects the PCB 110 to the power supply 130 when the button module 100 is assembled.

Referring to FIG. 5, the bottom portion 142 of the housing 140 has a landing portion 154 having a pair of locating pins 155. Each locating pin 155 is sized to be received in one of the pair of apertures 121 of the second part 112 of the PCB 110.

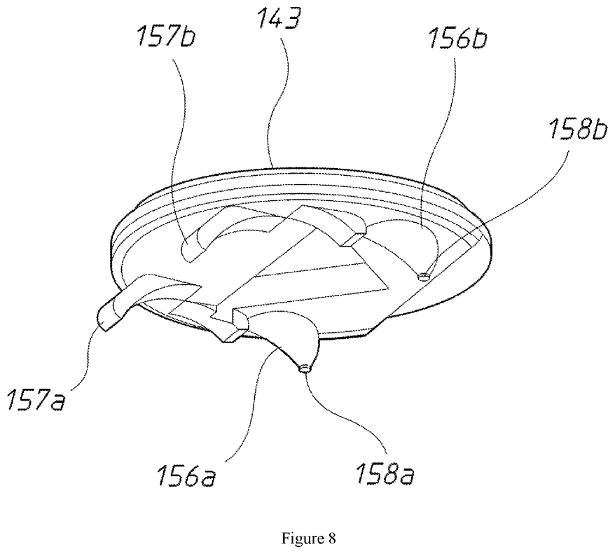

Referring to FIG. 8, the button 143 has a pair of protrusions 156a, 156b and a pair of locating arms 157a, 157b. Each protrusion 156a, 156b has a respective end portion 58a, 158b. The protrusions 156a, 156b are spaced such that each protrusion 156a, 156b aligns with a respective switch 120a, 120b of the PCB 110 when the button module 100 is assembled.

Assembly of the button module 100 will now be described. Referring to FIG. 7, each of the contact arms 150,151 are disposed within a respective channel 149 such that the hook portions 152, 153 of each contact arm 150, 151 are located within the slot 145 and the other end of each contact arm 150, 151 is located within the space 147. Referring to FIGS. 5 and 6, the first part 111 of the PCB 110 is inserted into the slot 145 until the first part 111 contacts the stop 146 of the slot 145. The flexible contacts 113 are then bent such that the second part 112 of the PCB 110 abuts the landing portion 154 of the bottom portion 142 and each of the locating pins 155 of the landing portion 154 are received in one of the pair of apertures 121 of the PCB 110. At this stage the hook portion 152, 153 of one of the contact arms 150, 151 will contact the first power supply contact 117 of the PCB 110 and the hook portion 152, 153 of the other contact arm 150, 151 will contact the second power supply contact 118a.

The power supply 130 is inserted into the space 147 such that a positive terminal 131 and a negative terminal 132 of the power supply 130 each contact a respective one of the contact arms 150, 151 within the space 147. It will be appreciated at this stage that the power supply 130 is electrically connected to the PCB 110 and is able to supply electrical power to the PCB 110.

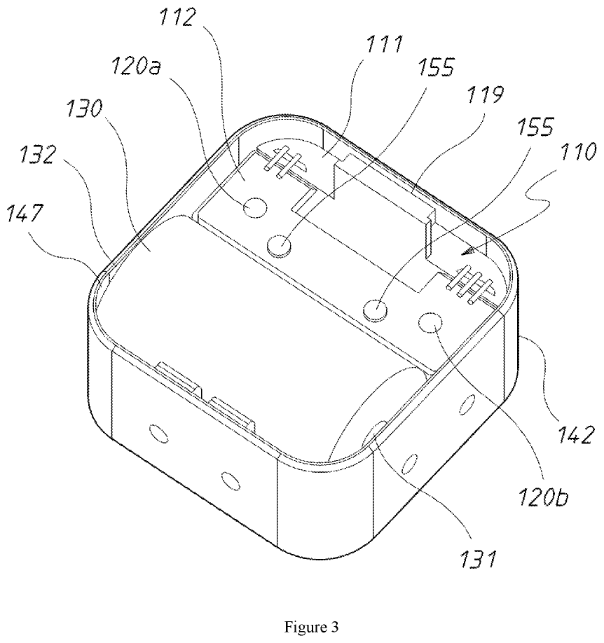

Referring to FIG. 3, it can be seen that the communications module 119 is disposed away from the power supply 130 to reduce any interference the power supply 130 may have on the communications module 119. For example, if the communications module 119 is too close to the power supply 130, then the power supply 130 may cause electromagnetic interference when the communications module 119 is communicating with one or more wireless devices over one or more wireless networks.

The button 143 is then disposed such that each protrusion 156a, 156b of the button 143 is aligned with one of the switches 120a, 120b of the PCB 110. To complete the assembly of the button module 100, the top portion 141 of the housing 140 is then coupled to the bottom portion 142 such that the button 143 is held in place by, and extends through, the top portion 141. The locating arms 157a, 157b of the button 143 are disposed within the housing 140 and are configured to retain the button 143 in the correct position with respect to the top portion 141 of the housing 140. It will be appreciated at this stage that, when the button 143 is actuated (e.g. pressed by a user), the end portions 158a, 158b of each protrusion 156a, 156b of the button 143 will depress the switches 120a, 120b of the PCB 110, which will close an electronic circuit of the PCB 110, thereby causing the PCB 110 to perform a function by executing one of more of the software application programs stored on the storage module 123 using the processor module 114.

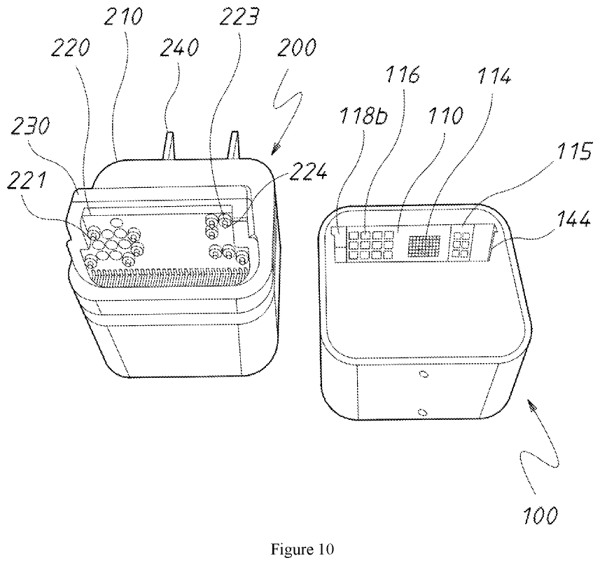

Referring to FIGS. 2 and 10, when the button module 100 is assembled, the PCB 110 partially defines the socket 144 and the first set of contact pads 115 and the second set of contact pads 116 are exposed within the socket 144. As the first set of contact pads 115 and the second set of contact pads 116 are exposed within the socket 144, the pads 115 and the pads 116 are able to be electrically connected to other electronic circuits of other electronic modules (discussed below).

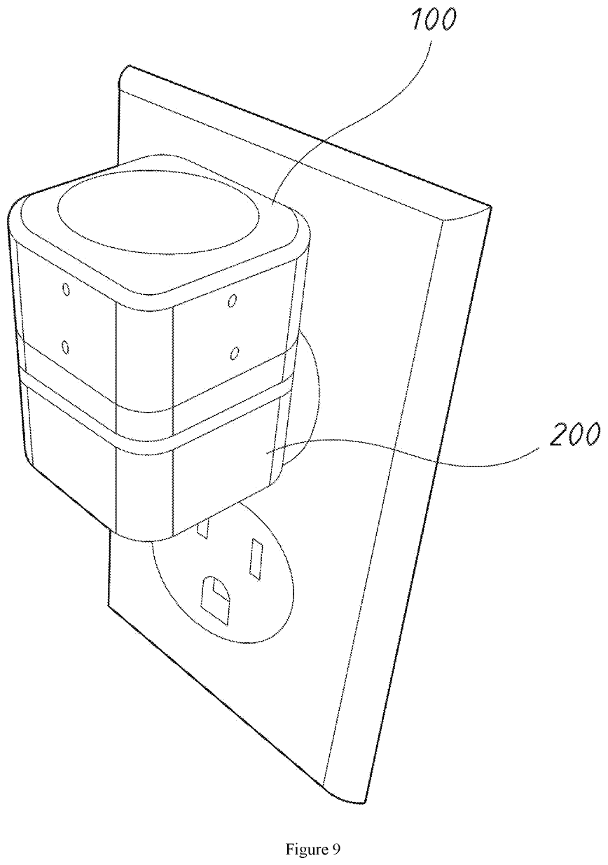

Referring to FIG. 9, the button module 100 is removably coupled to an electronic module 200. The electronic module 200 is coupled to mains electricity via a standard domestic power socket.

FIG. 10 shows the slot 144 of the button module 100 and how the PCB 110 partially defines the slot 144. As seen in FIG. 10, the first set of contact pads 115 and the second set of contact pads 116 are exposed within the slot 144 of the housing 140.

The electronic module 200 comprises a body 210, an electronic circuit 220, a plug 230, and an electrical adapter 240. The body 210 houses a circuit board (not shown) therein and the electronic circuit 220 is electrically connected to the circuit board and extends out of the body 210 such that the electronic circuit 220 is exposed. The electronic circuit 220 comprises a number of contacts 221 (only one numbered for clarity of illustration) that are each configured to contact one contact pad of the first set of contact pads 115 or one contact pad of the second set of contact pads 116 of the PCB 110. The electronic circuit 220 is formed as a plug 230 having a shape that complements that of the socket 144. The plug 230 may take any other suitable form known in the art, so long as each contact 221 of the electronic circuit 220 is able to electrically contact one contact pad of the first set of contact pads 115 or one contact pad of the second set of contact pads 116 of the PCB 110. It will be appreciated that the electronic circuit 220 forms at least part of the circuit board of the electronic module 200.

As can be seen from FIG. 10, the contacts 221 of the electronic circuit 220 are in the form of pogo pins. Each contact 221 comprises a base portion 223 and a pin portion 224. The pin portion 224 is biased so as to extend out from the base portion 223. The pin portion 224 of each contact 221 is able to retract into the base portion 223 when a force is applied to the end of the pin portion 224 that forces the pin portion 224 into the base portion 223. Although the contacts 221 have been described and illustrated as pogo pins, it will be appreciated that any other suitable contacts known in the art could be used for the contacts 221 such as, for example, spring contacts, leaf spring contacts, or the like.

As can be seen from FIG. 10, the PCB 110 sits vertically in the button module. The PCB in the vertical position has contact points, which are used to connect the button module with other devices or accessories. The button module can control the accessory by connecting thereto using the PCB 110 in the vertical position. The button modules act as a brain to the accessory and control various functions of the accessory. The PCB 110 in that vertical position allows for a low-cost, space limited plug to connect with the button module. The PCB 110 in another position may tend to increase the cost of manufacturing.

The electrical adapter 240 is configured to removably couple to a power source such as, for example, mains electricity. The electrical adapter 240 is electrically connected to the circuit board of the electronic module 200 so as to provide electrical power to the circuit board and the electronic circuit 220 when the electrical adapter 240 is coupled to a power source. It will be appreciated that the button module 100 is able to removably couple to one of a plurality of electronic modules 200, each of which may be capable of providing differing functionality to the button module 100. It will therefore also be appreciated that the plurality of electronic modules 200 are removable accessories to the button module 100 that are each capable of increasing the functionality of the button module 100.

Although the electronic module 200 is described and illustrated as having an electrical adapter 240, it is also envisaged that one or more of the plurality of electronic modules 200 may not have an electrical adapter 240 and such electronic modules 200 would receive electrical power from the power supply 130 when the respective electronic module 200 is coupled to the button module 100.

Each of the plurality of electronic modules 200 may be configured without a processor module and configured to respond to the processor module 114 of the PCB 110. The processor module 114 of the PCB 110 may be programmable using the software application programs stored in the storage module 123 to control one or more operations of each of the electronic modules 200 when a respective one of the plurality of electronic modules 200 is coupled to the button module 100. It will therefore be appreciated that each of the plurality of electronic modules 200 are operable when coupled to the button module 100 and are controlled by the processor module 114 of the PCB 110.

The plurality of electronic modules 200 may be configured without any communication modules. The modules 200 are able to communicate with one or more of the remote devices (e.g., 185) over one or more networks 181, 182 via communication modules of the button module 100. When one of the plurality of electronic modules 200 is removably coupled to the button module 100, components of the electronic module 200 may communicate with the one or more remote devices 185 over the one or more networks 181, 182 via the communications module 119 of the PCB 110, to which the electronic module 200 is electrically connected.

The button module 100 is removably couplable to an electronic module 200 by inserting the plug 230 of the electronic module 200 into the socket 144 of the button module 100. As the plug 230 has a shape that complements that of the socket 144, the plug 230 may be inserted into the socket 144 of the button module 100 when the plug 230 is correctly aligned with the socket 144.

When the plug 230 is inserted into the socket 144 of the button module 100, each of the contacts 221 of the electronic circuit 220 contact one contact pad of the first set of contact pads 115 or one contact pad of the second set of contact pads 116 of the PCB 110. The configuration of the contacts 221 of the electronic circuit 220 will determine the combination of the first set of contact pads 115 and the second set of contact pads 116 that are electrically contacted by the contacts 221. It will therefore be appreciated that electronic modules 200 having different configurations of the contacts 221 will contact different combinations of the first set of contact pads 115 and the second set of contact pads 116 of the PCB 110. Accordingly, the button module 100 is able to removably receive the electronic circuit 220 of a plurality of electronic modules 200 having different configurations of the contacts 221. It will also be appreciated that each of the plurality of electronic modules 200 will contact a different combination of the first set of contact pads 115 and the second set of contact pads 116 of the PCB 110 when the electronic circuit 220 of one of the plurality of electronic modules 200 is inserted into the socket 144 of the button module 100.

The software application programs executable by the processor module 114 of the PCB 110 are programmable to perform one or more different functions according to the combination of the first set of contact pads 115 and the second set of contact pads 116 contacted by the electronic module 200 coupled to the button module 100. Accordingly, it will be appreciated that the button module 100 may be programmed to perform different functions when different electronic modules 200 are coupled to the button module 100.

When the electronic circuit 220 of one of the plurality of electronic modules 200 is inserted into the socket 144 of the button module 100, one or more of the contacts 221 will electrically contact the second power contact 118b of the PCB 110. In this case, the electrical adapter 240 is electrically connected to the PCB 110 so that the electrical adapter 240 is able to provide electrical power to the PCB 110 and to the circuit board and electronic circuit 220 of the electronic module 200 when the electrical adapter 240 is coupled to a power source such as, for example, mains electricity.

When the electronic circuit 220 of one of the plurality of electronic modules 200 is inserted into the socket 144 of the button module 100, the PCB 110, the power supply 130, and the electronic circuit 220 are all electrically connected to each other. The power supply 130 is capable of providing electric power to the PCB 110 and the electronic circuit 220.

When the electrical adapter 240 of the electronic module 200 is coupled to a power source, the electrical adapter 240 is able to provide power to the PCB 110 and the electronic circuit 220. The power supply 130 does not provide electrical power to the PCB 110 or the electronic circuit 220, unless the power source is no longer able to provide electrical power or the electrical adapter 240 is removed from the power source. Accordingly, the power supply 130 is a back-up source of electrical power for the PCB 110 and the electronic circuit 220.

The software application programs stored on the storage module 123 of the PCB 110 of the button module 100 may be programmed to perform one or more functions and each of the electronic modules 200 may contain components that the PCB 110 may utilize to perform further functions that the PCB 110 would be incapable of performing without being coupled to the electronic module 200.

The software application programs stored on the storage module 123 of the PCB 110 may be programmed to perform different functions in response to the button 143 being actuated. When an electronic module 200 is removably coupled to the button module 100, the software application programs stored on the storage module 123 of the PCB 110 may also be programmed to utilize the electronic module 200 to perform functions in response to the button 143 being actuated.

The software application programs stored on the storage module 123 of the PCB 110 may be further programmed to perform different functions in response to the button 143 being actuated according to different predetermined sequences. When an electronic module 200 is removably coupled to the button module 100, the software application programs stored on the storage module 123 may also be programmed to utilize the electronic module 200 to perform different functions in response to the button 143 being actuated according to predetermined sequences. For example, pressing (i.e. actuating) the button 143 once may cause the PCB 110 to perform a predetermined function programmed on the processor module 114 and the PCB 110 may perform different functions when the button 143 is pressed according to predetermined sequences such as, for example, short-long-short sequence of button presses.

The LED 122 of the PCB 110 is configured to turn on when the button 143 has been actuated to notify a user that the button 143 has been actuated.

Use of the button module 100 will now be described. It will be appreciated that the button module 100 has two operating configurations, a first operating configuration where the button module 100 is not coupled to an electronic module 200, and a second operating configuration when the button module 100 is coupled to one of a plurality of electronic modules 200.

With regard to the first operating configuration, the software application programs stored on the storage module 123 of the PCB 110 may be programmed to perform one or more functions by a user. In such a configuration, the power supply 130 provides electric power to the PCB 110. The software application programs stored on the storage module 123 of the PCB 110 may be programmed to continuously, or periodically, perform one or more functions (e.g. monitor temperature, smoke, etc.) and/or perform one or more functions in response to the button 143 being actuated according to one or more different predetermined (i.e. programmed) sequences. The PCB 110 is therefore able to perform one or more functions using the software application programs executed by the processor module 114 independent of the button 143 being actuated and also perform one or more functions using the software application programs executed by the processor module 114 in response to the button 143 being actuated.

With regard to the second operating configuration, when one of the plurality of electronic modules 200 is removably coupled to the button module 100, the circuit board and the electronic circuit 220 of the electronic module 200 are electrically connected to the PCB 110 and the power supply 130 of the button module 100. When the electrical adapter 240 of the electronic module 200 is not coupled to a power source such as, for example, mains electricity, the power supply 130 provides electric power to the PCB 110 and the circuit board and electronic circuit 220 of the electronic module 200. When the electrical adapter 240 of the electronic module 200 is coupled to a power source, the PCB 110 and the circuit board and electronic circuit 220 of the electronic module 200 are powered by the power source via the electrical adapter 240. The power supply 130 is a back-up source of electrical power in case the power source is not able to provide electrical power or the electrical adapter 240 is no longer coupled to the power source. Accordingly, in the second operating configuration, the PCB 110 and the circuit board and electronic circuit 220 of the electronic module 200 may be powered by the power supply 130 or mains electricity.

In the second operating configuration, the software application programs stored on the storage module 123 of the PCB 110 may be programmed to continuously, or periodically, perform one or more functions (e.g. monitor temperature, smoke, etc.) and/or perform one or more functions in response to the button 143 being actuated according to one or more different predetermined (i.e. programmed) sequences. The software application programs stored on the storage module 123 of the PCB 110 may be further programmed to utilize the electronic module 200 to continuously, or periodically, perform one or more functions (e.g. monitor temperature, smoke, etc.) and/or to utilize the electronic module 200 to perform one or more functions in response to the button 143 being actuated according to one or more different predetermined (i.e. programmed) sequences.

In the second operating configuration, the PCB 110 is therefore able to perform at least one function using the software application programs executed by the processor module 114 independent of the button 143 being actuated and also perform at least one function programmed on the processor module 114 in response to the button 143 being actuated. Further, the PCB 110 is able to utilize the electronic module 200 to perform at least one function using the software application programs executed by the processor module 114 independent of the button 143 being actuated and also to utilize the electronic module 200 to perform at least one function programmed on the processor module 114 in response to the button 143 being actuated.

One or more of the functions of the PCB 110 may involve communicating and/or controlling one or more of the remote devices 185 over the one or more communication networks 181, 182. The communications module 119 of the PCB 110 is configured to transmit signals from the PCB 110 to the one or more remote devices 185 and to transmit signals from the one or more remote devices 185 to the PCB 100 over the one or more networks 181, 182.

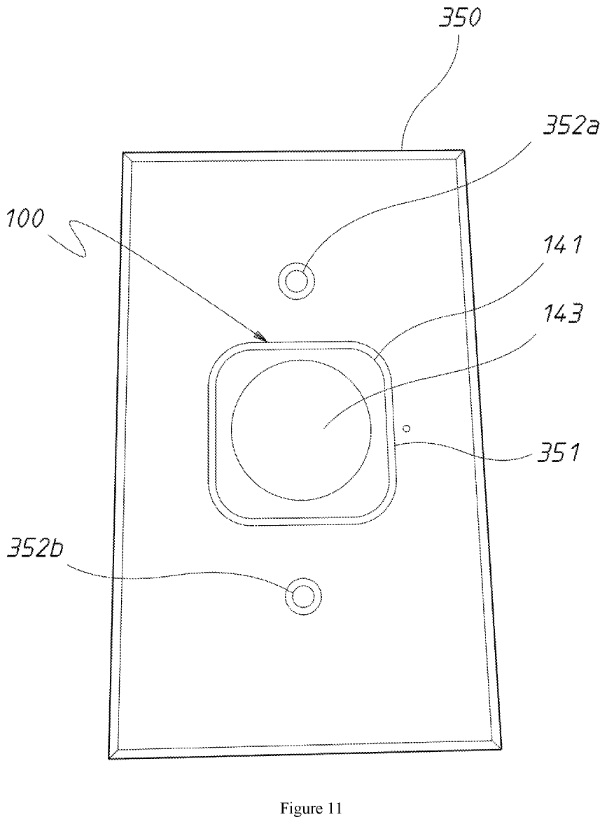

FIG. 11 shows the button module 100 installed in a wall. The button module 100 is installed in the wall using a mounting plate 350. The mounting plate 350 has an orifice 351 for receiving the button module 100 such that the button 143 of the button module 100 is exposed and can be actuated. The mounting plate 350 also has a pair of mounting holes 352a, 352b that allow the mounting plate 350 and the button module 100 to be installed in a wall by receiving a fastener through each mounting hole 352a, 352b.

The mounting plate 350 may replace traditional light switches with a button module 100. In this case, a user would be able to turn on/off a light by actuating the button 143 of the button module 100.

The PCB 110 of the button module 100 may be programmed to connect with a particular mobile electronic device such as, for example, a mobile phone, over a wireless network (e.g. Bluetooth®, Wi-Fi, etc.) when that particular mobile electronic device is in close proximity to the button module 100. The PCB 110 of the button module 100 may also be programmed to turn on a light when it connects to a particular mobile electronic device over a wireless network and to turn off the light when the button module 100 is no longer connected to the particular mobile electronic device over the wireless network. Accordingly, the button module 100, which may or may not be mounted using the mounting plate 350, may be programmed to turn on a light when a user enters a room carrying a particular mobile electronic device and to turn off the light when the person carrying the particular mobile electronic device exits the room.

The software application programs stored on the storage module 123 of the button module 100 may be programmed and reprogrammed to perform one or more of the following functions, for example, or be used as:
An emergency button. Actuating the button 143 may send an emergency message to one or more medical professionals such as, for example, doctors, ambulances, or the like;
A shopping/food ordering button. Actuating the button 143 according to different sequences may cause the button module 100 to purchase or order food items that are programmed to be associated with a particular so sequence.
Temperature sensor. The button module 100 may be programmed to continuously, or periodically, monitor the surrounding temperature. The button module 100 may be further programmed to send a control signal to an air conditioner to operate the air conditioner in response to the temperature falling below, or going above, a predetermined temperature. The button module 100 may also be placed inside a refrigerator or a freezer and send a notification if the temperature in the refrigerator or the freezer rises above a threshold value, thereby notifying a user that the seals on the refrigerator or freezer may be failing.
Send messages. The button module 100 may be programmed to send a predetermined message to a particular person over a particular network in response to the button 143 being actuated.
Send SMS and make calls. The button module 100 can be programmed to send an SMS and/or make phone calls through a connected device such as, for example, a mobile phone.
Mail notification. The button module 100 may be mounted on a post box and when a postman delivers mail the postman actuates the button 143, which will then send a notification that there is mail in the post box.
Remote control. The button module 100 may be programmed to act as a remote control for garage doors and lights for example.
Timer. The button module 100 may be programmed to act as a timer and send control signals to one or more wireless devices either when the time has finished or within a predetermined time range.
Personal alarm. The button module 100 may be programmed to send a notification to a security service or police when the button 143 is actuated. Accordingly, when in danger, a user may actuate the button 143, which will then notify the security service or police.
Proximity alarm. The PCB 110 of the button module 100 may be programmed to remain connected to a mobile electronic device such as, for example, a mobile phone, over a wireless network when the button module 100 is within range of the mobile electronic device. It will be appreciated that the button module 100 will not be connected to the mobile electronic device over a wireless network when the button module is not in range of the mobile electronic device. A software application installed on the mobile electronic device may be programmed to detect when the button module 100 is no longer connected to the mobile electronic device and issue an alarm that the button module 100 is no longer within range of the mobile electronic device. This feature can be used to help prevent theft and loss of personal items. For example, a user may place a button module 100, which is connected to their mobile phone via a wireless network, in their bag. If the bag is left behind or is stolen, the button module 100 may no longer be in range of the mobile phone and the software application installed on the mobile phone will issue an alarm alerting the user that the button module 100 is no longer in range and that therefore they have forgotten their bag or that their bag has been stolen.

It will be appreciated that the above list of functions is only provided as an example and that the button module 100 could be programmed to be used or perform a number of functions that are not included in the above list.

Each of the plurality of electronic modules 200 is a removable accessory that is capable of being coupled to the button module 100 to increase the functionality of the button module 100. Each of the plurality of electronic modules 200 is a removable accessory that may be configured to allow the button module 100 to function as one or more of the following (when the respective electronic module 200 is removably coupled to the button module 100):
Water detection accessory;
Voice box—When the button 143 of the button module 100 is actuated, an amplifier and microphone in the voice box is activated to detect and record a user's voice. The voice box may also have a speaker to ask a user questions such as, for example, “what would you like to add to your shopping list?” By replying verbally with particular shopping items, the microphone records the user's voice and forwards this recording to the button module 100. The button module 100 transfers the recording to a server that processes the recording and converts the recording to text. The text is then sent to a software application, which is configured to control the button module 100, that lists all the shopping items said by the user, such that the user can later refer to the list. Alternatively, the button module may be programmed such that when a user actuates the button 143 of the button module 100 after the list has been generated, the button module 100 orders all the shopping items in the list;
Light switch replacement;
Alarm;
Motion detector;
Temperature sensor;
Moisture, pH, and temperature soil probe;
Smoke detector;
Air conditioner controller;
Irrigation controller;
Garage door remote control;
Proximity sensor;
Global System for Mobile Communications (GSM) module, such that the button module 100 can communicate over the GSM network; and/or
Global satellite positioning (GPS) system such that the button module 100 can be used for GPS services.

It will be appreciated that the above list of functions performed by electronic modules 200 is only provided as an example and that each of the electronic modules 200 could provide the button module 100 with more functionality beyond what is listed above. It will be appreciated that the person skilled in the art would know which commercially available electrical components to use in an electronic module 200 to allow the button module 100 to perform one or more of the functions listed above.

In the first configuration (i.e. when the button module is not coupled to an electronic device), the button module 100 may further comprise a cover (not shown) that envelops the housing 140 of the button module 100 to waterproof the button module 100 and prevent the ingress of water into the button module 100. For example, the button module 100 with the cover may be disposed in a pool to monitor and notify a user of the temperature of the pool. The cover may be, for example, made from silicon.

In the second configuration (i.e. when the button module 100 is coupled to an electronic module 200), a cover (not shown) may be used to envelop both the button so module 100 and the electronic module 200 that is coupled to the button module 100 to prevent the ingress of water into the button module 100 and the electronic module 200 coupled to the button module 100. Similar to above, this may allow the button module 100 and the electronic module 200 to be disposed in a pool for example.

It will be appreciated that the button module 100 is capable of performing many functions on its own and that the functionality of the button module 100 may be further increased by the ability of the button module 100 to removably couple to a plurality of electronic modules 200. As the electronic modules 200 are removably coupled to the button module 100, the functionality of the button module 100 may be easily changed depending on the needs of the user by simply changing which electronic module 200 is coupled to the button module 100.

If none of the electronic modules 200 are configured to directly communicate over a network such as, for example, Wi-Fi, Bluetooth, or the like, none of the electronic modules 200 have to be tested to determine if they comply with the requirements of one or more wireless networks. Accordingly, only the button module 100 needs to be tested to determine if the button module 100 complies with the requirements of one or more wireless networks. This means that any new electronic modules 200 that are developed do not need to go through expensive testing to determine if they are compliant with the requirements of one or more wireless networks.

Although the button module 100 and the electronic modules 200 have been described with reference to preferred embodiments, it will be appreciated by persons skilled in the art that the invention may be embodied in many other forms.

Embodiments of the present invention may be provided as a computer program product, which may include a machine-readable storage medium tangibly embodying thereon instructions, which may be used to program a computer (or other electronic devices) to perform a process. The machine-readable medium may include, but is not limited to, fixed (hard) drives, magnetic tape, floppy diskettes, optical disks, compact disc read-only memories (CD-ROMs), and magneto-optical disks, semiconductor memories, such as ROMs, PROMs, random access memories (RAMs), programmable read-only memories (PROMs), erasable PROMs (EPROMs), electrically erasable PROMs (EEPROMs), flash memory, magnetic or optical cards, or other type of media/machine-readable medium suitable for storing electronic instructions (e.g., computer programming code, such as software or firmware).

Various methods described herein may be practiced by combining one or more machine-readable storage media containing the code according to the present invention with appropriate standard computer hardware to execute the code contained therein. An apparatus for practicing various embodiments of the present invention may involve one or more computers (or one or more processors within a single computer) and storage systems containing or having network access to computer program(s) coded in accordance with various methods described herein, and the method steps of the invention could be accomplished by modules, routines, subroutines, or subparts of a computer program product.

This PCT application incorporates by reference AU 2018902866, filed Aug. 7, 2018.

From the foregoing, it will be observed that numerous variations and modifications may be effected without departing from the spirit and scope of the invention. It is to be understood that no limitation with respect to the specific apparatus illustrated herein is intended or should be inferred.

1. A button module comprising:
a housing having an electrical connector and a button;
a circuit board disposed within the housing; and
wherein the button module comprises:
a first operating configuration in which the circuit board is configured to perform one or more functions programmed on the circuit board independent of the button and/or perform one or more functions programmed on the circuit board in response to actuation of the button; and
a second operating configuration in which an electronic circuit of one of a plurality of electronic modules is removably electrically connected to the electrical connector of the circuit board, the circuit board being configured to utilize the electronic circuit to perform one or more functions programmed on the circuit board independent of the button being actuated and/or to utilize the electronic circuit to perform one or more functions programmed on the circuit board in response to actuation of the button.

2. The button module of claim 1, wherein the circuit board disposed within the housing is in a vertical position.

3. The button module of claim 1, further comprising a power supply disposed within the housing, the power supply being electrically connected to the circuit board to supply power to the circuit board, and the one of a plurality of electronic modules is electrically connected to the power supply when the electronic circuit of the one of a plurality of electronic modules is removably electrically connected to the electrical connector.

4. The button module of claim 1, wherein the circuit board is configured to communicate with one or more wireless devices over one or more wireless networks.

5. A button module comprising:
a housing having a socket and a button;
a circuit board disposed within the housing in the vertical position, the circuit board being configured to communicate with one or more wireless devices over one or more wireless networks; and
a power supply disposed within the housing, the power supply being electrically connected to the circuit board to supply power to the circuit board,
wherein the button module comprises:
a first operating configuration in which the circuit board is configured to perform one or more functions programmed on the circuit board independent of the button and/or perform one or more functions programmed on the circuit board in response to actuation of the button; and
a second operating configuration in which an electronic circuit of one of a plurality of electronic modules is removably received in the socket such that the electronic circuit is electrically connected to the circuit board and the power supply, the circuit board being configured to utilize the electronic circuit to perform one or more functions programmed on the circuit board in response to actuation of the button.

6. The button module of claim 5, wherein, in the second operating configuration, the electronic circuit is powered by the power supply.

7. The button module of claim 5, wherein, in the second operating configuration, the circuit board controls an operation of the electronic circuit.

8. The button module of claim 5, wherein, in the second operating configuration, the respective electronic module is configured to communicate with the one or more wireless devices over the one or more wireless networks via the circuit board.

9. The button module of claim 5, wherein the electronic circuit is configured as a plug to be received in the socket.

10. The button module of claim 9, wherein the plug has a shape that complements a shape of the socket.

11. The button module of claim 5, wherein, in the second operating configuration, the housing is removably coupled to the respective electronic module.

12. The button module of claim 5, wherein, in the second operating configuration, the electronic module coupled to the button module is configured to removably couple to mains electricity such that the circuit board is configured to receive power from the power supply and/or mains electricity.

13. The button module of claim 12, wherein the electronic circuit is configured to be powered by mains electricity and/or the power supply.

14. The button module of claim 5, wherein the circuit board has one or more communication modules configured to communicate with the one or more wireless devices over the one or more wireless networks.

15. The button module of claim 5, wherein the power supply is a battery.

16. The button module of claim 5, wherein, in the first operating configuration, a water-proof cover encloses the housing to restrict the ingress of water into the housing.

17. The button module of claim 5, wherein, in the second operating configuration, a water-proof cover encloses the housing and the respective electronic module to restrict the ingress of water into the housing and the electronic module.

18. The button module of claim 1, wherein, in the first operating configuration, the circuit board is configured to perform at least one of the one or more functions in response to the button being actuated according to a predetermined sequence.

19. The button module of claim 5, wherein, in the second operating configuration, the circuit board is configured to perform at least one of the one or more functions programmed on the circuit board in response to the button being actuated according to a predetermined sequence.

20. (canceled)

21. (canceled)

22. (canceled)

23. (canceled)

24. (canceled)

25. (canceled)

26. (canceled)

27. (canceled)

28. The button module according to claim 1, wherein the button and circuit board programming are responsive to a select sequence of timing and duration of button pushing to input commands.
